(19) United States
(12) Patent Application Publication
(10) Pub. No.: US 2017/0082574 A1
(43) Pub. Date: Mar. 23, 2017

(54) GAS SENSOR AND METHOD OF FABRICATING THE SAME

(71) Applicant: Korea Institute of Science and Technology, Seoul (KR)

(72) Inventors: Young Tae BYUN, Seoul (KR); Jae Seong KIM, Seoul (KR); Je Haeng LEE, Seoul (KR); Sun Ho KIM, Seoul (KR); Young Min JHON, Seoul (KR); Sun Woo CHOI, Seoul (KR)

(73) Assignee: Korea Institute of Science and Technology, Seoul (KR)

(21) Appl. No.: 15/254,322

(22) Filed: Sep. 1, 2016

(30) Foreign Application Priority Data
Sep. 21, 2015 (KR) 10-2015-0133025

(51) Int. Cl. G01N 27/414; C23C 14/34; H01L 51/00; B82Y 15/00; B82Y 40/00; B22F 1/02; C23C 14/18; C23C 14/58

(52) U.S. Cl. CPC G01N 27/4141; C23C 14/185; C23C 14/34; C23C 14/5806; B82Y 15/00; B82Y 40/00; B22F 1/025; H01L 51/0003; H01L 51/0096; H01L 51/0048; H01L 51/0026; B22F 2301/25; B22F 2304/054; B22F 2302/403

(57) ABSTRACT

A gas sensor and a method of fabricating the same are provided. The gas sensor includes a substrate, carbon nanotubes (CNTs) adsorbed onto the substrate, platinum nanoparticles (NPs) decorated to surfaces of the CNTs, and an electrode formed on the substrate onto which the CNTs with the platinum NPs decorated thereto are adsorbed. When the platinum NPs and CNTs are used as a sensing material, the gas sensor can be useful in sensing gases with high sensitivity even when present at a low concentration of at least 2 ppm and stably sensing noxious gases such as C₆H₆, C₇H₈, C₃H₆O, CO, NO, and NH₃ as well as NO₂, and can have particularly excellent selectivity and response characteristics with respect to NO₂ gas.

### CROSS-REFERENCE TO RELATED APPLICATION

This application claims priority to and the benefit of Korean Patent Application No. 2015-0133025, filed on Sep. 21, 2015, the disclosure of which is incorporated herein by reference in its entirety.

### BACKGROUND

1. Field of the Invention

The present invention relates to a gas sensor and a method of fabricating the same, and more particularly, to a gas sensor using platinum nanoparticles (NPs) and carbon nanotubes (CNTs) as a sensing material, and a method of fabricating the same.

2. Discussion of Related Art

Various gases generated due to industrialization and urbanization cause air pollution. Although gases from factories occupied the majority of the gases in the past, exhaust gases from cars have increased. Exhaust gases from cars are mainly composed of components such as unburned hydrocarbons (CHₓ), nitrogen oxides (NOₓ), carbon monoxide (CO), carbon dioxide (CO₂), and steam. Among these, nitrogen oxide (NOₓ) gases are the main causes of environmental pollution such as photochemical smog, acid rain, and the like as well as severe respiratory disorders in humans. For example, when nitrogen dioxide (NO₂) gas is present in the air at a concentration of 20 ppm or more, nitrogen dioxide (NO₂) gas is harmful to humans, and it may cause asthma even when present at a low concentration. Emissions of such NOₓ gases have continually increased due to an explosive increase in automobiles, and thus regulation of NOₓ gas emission has been strengthened due to severe environmental problems and issues regarding the improvement in quality of life. Therefore, there is an increasing demand for sensors configured to sense toxic gases which serve as a source of air pollution.

In general, a gas sensor distinguishes gas molecules using an ability of the gas molecules to be adsorbed onto a solid surface when the gas molecules come into contact with the solid surface. That is, the gas sensor is operated based on the principle that an amount of noxious gases is measured using a property of the gas sensor whose electrical conductivity varies according to an adsorption level of the gas molecules. Such a gas sensor is generally used to sense and rapidly response to combustible or toxic gases at an early stage. Thus, a large number of gas sensors using various detection methods have been developed, and they may be divided into electrochemical gas sensors, catalytic combustion gas sensors, solid electrolyte gas sensors, semiconductor gas sensors, etc., depending on the detection principle.

The semiconductor gas sensor is a sensor that detects a certain chemical component or adjusts the chemical component to a certain level using changes in electric resistance and work functions of a semiconductor device in a constant atmosphere and mainly targets a combustible gas, but may also detect oxidative gases having a high adsorption strength such as oxygen, steam, and nitrogen dioxide. Its sensing material includes a metal oxide semiconductor material such as SnO₂, a solid electrolyte material, various organic materials, a complex of carbon black and an organic substance, etc.

However, a gas sensor made of such a material has various problems. A gas sensor in which a metal oxide semiconductor material or solid electrolytes are used is normally operated only when the gas sensor is heated to a temperature of 200° C. to 600° C. or more. In this case, the gas sensor has technical limits on selectivity as a property of selectively sensing only a desired gas in a mixed gas atmosphere. Also, the gas sensor has drawbacks in that it has very low electrical conductivity when an organic material is used, and has very low sensitivity when a complex of carbon black and an organic substance is used.

On the other hand, carbon nanotubes (CNTs) have advantages in that they enable a gas sensor to operate at room temperature and have good sensitivity and a fast response time. Such advantages are due to physical properties of CNTs. In general, CNTs are tube-shaped molecules formed by rolling a graphite sheet made of carbon atoms linked in hexagonal rings, and have a diameter ranging from several to several tens of nanometers (nm). CNTs have high strength, are easily flexed, and are not substantially damaged or worn down even when the CNTs are used repeatedly. Also, their electrical characteristics vary according to a rolling pattern, a structure, and a diameter of the CNTs. Also, CNTs may be widely used in various industrial fields since CNTs have excellent electron emission properties and chemical stability. In particular, CNTs are useful in the field of applications for detection of a trace of a chemical component or hydrogen storage since CNTs have high surface reactivity due to high surface area-to-volume ratios of CNTs.

Referring to Non-patent Document 1, results of determining functions as a gas sensor using CNTs are provided by Professor Dai's team at Stanford University in Stanford, Calif., United States. The results show that electrical conductivity of single-walled CNTs (SWCNTs) varies according to gases exposed thereto, suggesting a possibility of detecting ammonia (NH₃) and nitrogen dioxide (NO₂) gases. However, a gas sensor using SWCNTs in a pure state as disclosed in Non-patent Document 1 has a drawback in that it cannot stably sense NO₂ gas due to poor response characteristics (a response time, a recovery time, reversibility, and sensitivity) with respect to gases. Specifically, the gas sensor has a drawback in that it has a very slow response time and a long recovery time with respect to gases and shows poor reversibility and sensitivity.

In addition, a variety of conventional sensors using methods using CNTs, such as a method using multi-walled CNTs (MWCNTs), a method using a CNT thin film, a method using a CNT-gold nanoparticle complex, etc., are disclosed in Non-patent Documents 2 to 9. However, there is a demand for gas sensors which can more stably sense NO₂ gas and show excellent response characteristics, that is, a reduced response time and recovery time, high sensitivity, and excellent reversibility.

### PRIOR-ART DOCUMENTS

### Non-Patent Documents

(Non-patent Document 0001) J. Kong et al., Nanotube molecular wires as chemical sensors, Science, Vol. 287, (2000) 622-625

(Non-patent Document 0002) L. Valentini et al., Investigation of the NO₂ sensitivity properties of multiwalled CNTs prepared by plasma-enhanced chemical vapor deposition, Journal of Vacuum Science & Technology B 21, 1996 (2003)

(Non-patent Document 0003) Jing Li et al., CNT Sensors for Gas and Organic Vapor Detection, Nano Lett., Vol. 3, No. 7, 2003, 929-933

(Non-patent Document 0004) L. Valentini et al., Role of defects on the gas sensing properties of CNTs thin films. Chemical Physics Letters 387 (2004) 356-361

(Non-patent Document 0005) L. Valentini et al., Sensors for sub-ppm NO₂ gas detection based on CNT thin films, Applied Physics Letters 82, 961 (2003)

(Non-patent Document 0006) I. Sayago et al., CNT networks as gas sensors for NO₂ detection, Talanta 77 (2008) 758-764

(Non-patent Document 0007) Hu Young Jeong et al., Flexible room-temperature NO₂ gas sensors based on CNTs/reduced graphene hybrid films, Applied Physics Letters 96, 213105 (2010)

(Non-patent Document 0008) M. Penza et al., Effect of growth catalysts on gas sensitivity in CNT film based chemiresistive sensors, Applied Physics Letters 90, 103101 (2007)

(Non-patent Document 0009) Philip Young et al., High-Sensitivity NO₂ Detection with CNT-Gold NP Composite Films, Journal of Nanoscience and Nanotechnology Vol. 5, 1509-1513, 2005

### SUMMARY OF THE INVENTION

The present invention is directed to a gas sensor capable of operating at room temperature (RT) and showing excellent response characteristics to noxious gases such as NO₂, C₆H₆, C₇H₈, C₃H₆O, CO, NO, NH₃, etc., and a method of fabricating the same.

Also, the present invention is directed to a gas sensor capable of showing excellent selectivity to NO₂ gas, and a method of fabricating the same.

According to an aspect of the present invention, there is provided a gas sensor which includes a substrate, carbon nanotubes (CNTs) adsorbed onto the substrate, platinum nanoparticles (NPs) decorated to surfaces of the CNTs, and an electrode formed on the substrate onto which the CNTs with the platinum NPs decorated thereto are adsorbed.

According to another aspect of the present invention, there is provided a method of fabricating a gas sensor, which includes (a) adsorbing CNTs onto a substrate, (b) depositing the platinum (Pt) onto the substrate onto which the CNTs are adsorbed, and (c) heat-treating the substrate onto which the platinum (Pt) is deposited to form platinum (Pt) NPs on surfaces of the CNTs.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a diagram schematically showing an operation of adsorbing carbon nanotubes (CNTs) on a substrate according to one exemplary embodiment of the present invention;

FIG. 2 is a diagram schematically showing an operation of depositing platinum (Pt) on the substrate on which the CNTs are adsorbed as shown in FIG. 1 and an operation of heat-treating the substrate onto which the platinum (Pt) is deposited;

FIG. 3 is a diagram schematically showing an operation of forming an electrode on the substrate that underwent the heat treatment operation as shown in FIG. 2;

FIG. 4 is a transmission electron microscope image of the substrate that underwent the heat treatment operation in a fabricating method as shown in FIG. 2;

FIG. 5 is an enlarged transmission electron microscope image showing a portion of the transmission electron microscope image shown in FIG. 4;

FIG. 6 is an enlarged transmission electron microscope image showing a portion of the transmission electron microscope image shown in FIG. 5;

FIG. 7 is a graph illustrating resistance values measured over time when 2 ppm of nitrogen dioxide (NO₂) gas is applied to a gas sensor fabricated in Example 1;

FIG. 8 is a graph illustrating resistance values measured over time when 2 ppm of benzene (C₆H₆) gas is applied to the gas sensor fabricated in Example 1;

FIG. 9 is a graph illustrating resistance values measured over time when 2 ppm of toluene (C₇H₈) gas is applied to the gas sensor fabricated in Example 1;

FIG. 10 is a graph illustrating resistance values measured over time when 2 ppm of acetone (C₃H₆O) is applied to the gas sensor fabricated in Example 1;

FIG. 11 is a graph illustrating resistance values measured over time when 2 ppm of carbon monoxide (CO) gas is applied to the gas sensor fabricated in Example 1;

FIG. 12 is a graph illustrating resistance values measured over time when 2 ppm of ammonia (NH₃) gas is applied to the gas sensor fabricated in Example 1;

FIG. 13 is a graph illustrating resistance values measured over time when 2 ppm of nitrogen monoxide (NO) gas is applied to the gas sensor fabricated in Example 1;

FIG. 14 is a graph illustrating a comparison of sensitivities of the gas sensor fabricated in Example 1 according to types of gas when 2 ppm of NO₂, C₆H₆, C₇H₈, C₃H₆O, NH₃, CO and NO gases are applied to the gas sensor;

FIG. 15 is a graph illustrating a comparison of normalized resistance values of a CNT (a pristine single-walled CNT (SWCNT)) gas sensor, onto which platinum nanoparticles (NPs) are not decorated, and a CNT (a Pt-SWCNT) gas sensor, onto which platinum NPs are decorated, with respect to NO₂ gas over time, as measured at room temperature (RT); and

FIG. 16 is a graph illustrating a comparison of normalized resistance values of the CNT (a pristine SWCNT) gas sensor, onto which platinum NPs are not decorated, and the CNT (a Pt-SWCNT) gas sensor, onto which platinum NPs are decorated, with respect to NO₂ gas over time, as measured at 100° C.

### DETAILED DESCRIPTION OF EXEMPLARY EMBODIMENTS

Exemplary embodiments of the present invention will be described in detail below with reference to the accompanying drawings. While the present invention is shown and described in connection with exemplary embodiments thereof, it should be apparent to those skilled in the art that various modifications can be made without departing from the scope of the invention.

Unless specifically stated otherwise, all of the technical and scientific terms used in this specification have the same meanings as that which are generally understood by a person skilled in the related art to which the present invention belongs. In general, the nomenclature used in this specification and the experimental methods described below are widely known and generally used in the related art.

The present invention is directed to a gas sensor which includes a substrate, carbon nanotubes (CNTs) adsorbed onto the substrate, platinum nanoparticles (NPs) decorated to surfaces of the CNTs, and an electrode formed on the substrate onto which the CNTs with the platinum NPs decorated thereto are adsorbed.

Hereinafter, a gas sensor according to one exemplary embodiment of the present invention will be described in further detail.

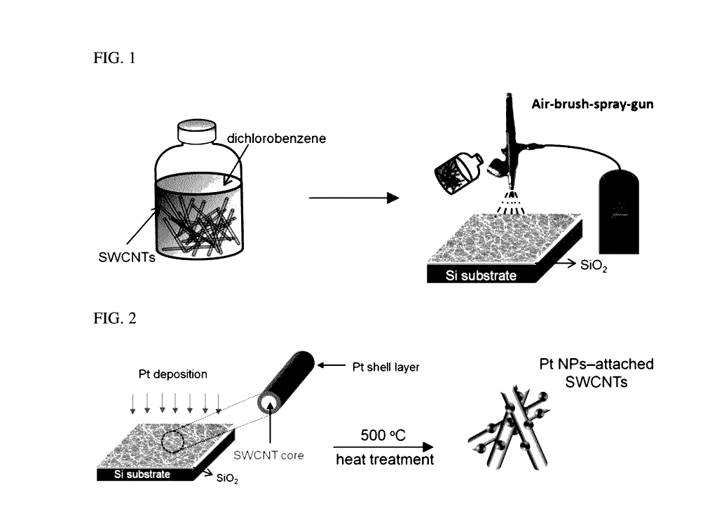

A Group III-V compound semiconductor material such as Si, GaAs, InP, InGaAs, etc., a glass, an oxide thin film, a dielectric thin film, and a metal thin film may be used as a material used for the substrate, but the present invention is not limited thereto. Preferably, the substrate may include a silicon substrate, more preferably a silicon substrate having an insulator film formed on a surface thereof. For example, the substrate may be a silicon substrate having a silicon oxide (SiO₂) film formed on a surface thereof, as shown in FIG. 1.

In the present invention, CNTs and platinum (Pt) NPs are used as a sensing material. As described above, when CNTs are used as the sensing material rather than an oxide, a gas sensor capable of being operable at room temperature (RT) may be provided. CNTs are formed by rolling a graphite sheet of a hexagonal honeycomb structure in a straw shape, and thus have a single-walled (SW), double-walled (DW) or multi-walled (MW) structure. CNTs may have electrical conductive or semiconductive characteristics in a rolling direction. CNTs include single-walled CNTs (SWCNTs) because SWCNTs exhibit superior performance to multi-walled CNTs (MWCNTs) in terms of sensitivity and response time.

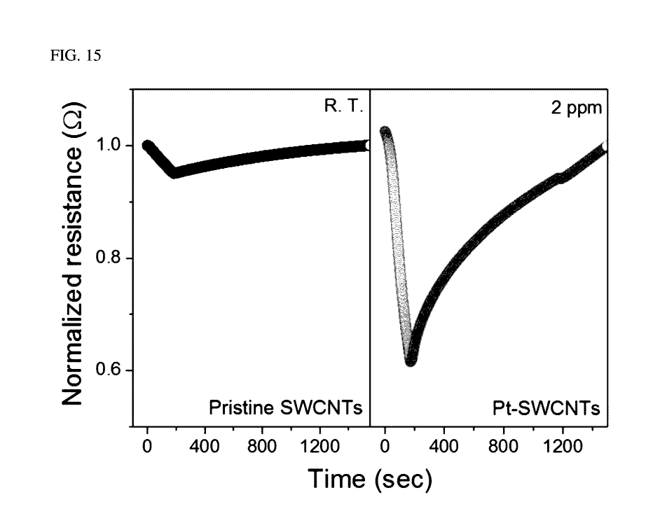

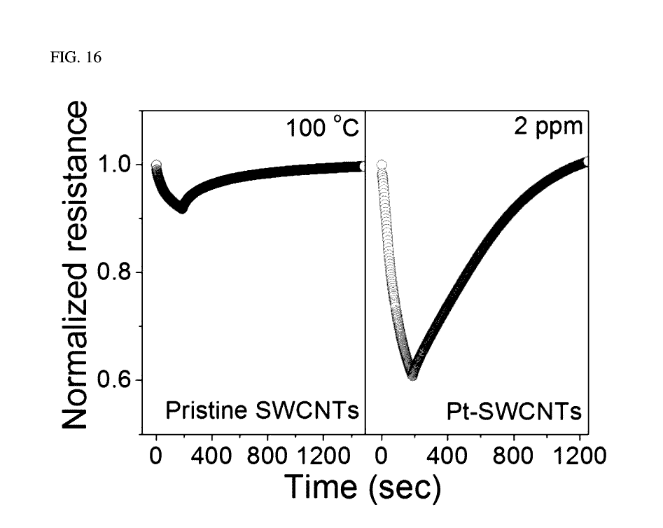

Also, in the present invention, since platinum NPs are used as the sensing material together with CNTs, a gas sensor exhibiting very good sensitivity to react with a trace of noxious gases may be provided. The platinum NPs play a role as a catalyst in forcing the CNTs to sense NO₂ gas. In this case, a catalytic reaction may be activated as the platinum NPs may have a smaller average diameter and may be present in an uncoupled state. Specifically, FIGS. 15 and 16 are graphs illustrating a comparison of normalized resistance values of a CNT (a pristine SWCNT) gas sensor, onto which platinum NPs are not decorated, and a CNT (a Pt-SWCNT) gas sensor, onto which platinum NPs are decorated, with respect to NO₂ gas over time, as measured at RT and 100° C., respectively. Referring to FIGS. 15 and 16, it can be seen that a change in resistance is clearly observed at both RT and the temperature of 100° C. when the platinum NPs are decorated onto surfaces of the CNTs. In this case, the normalized resistance value represents a percentage of a resistance value over time with respect to a resistance value at zero seconds.

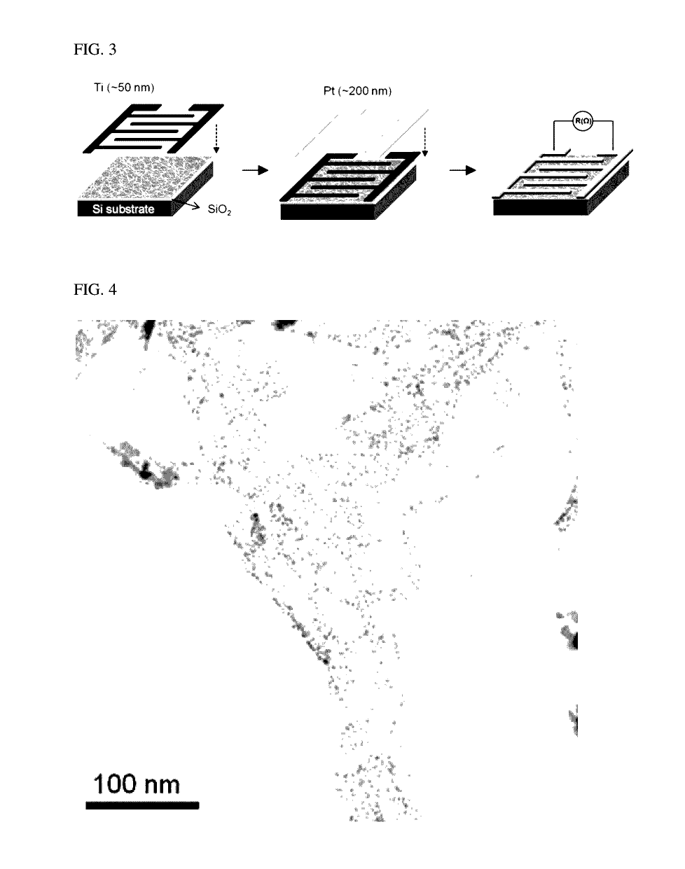

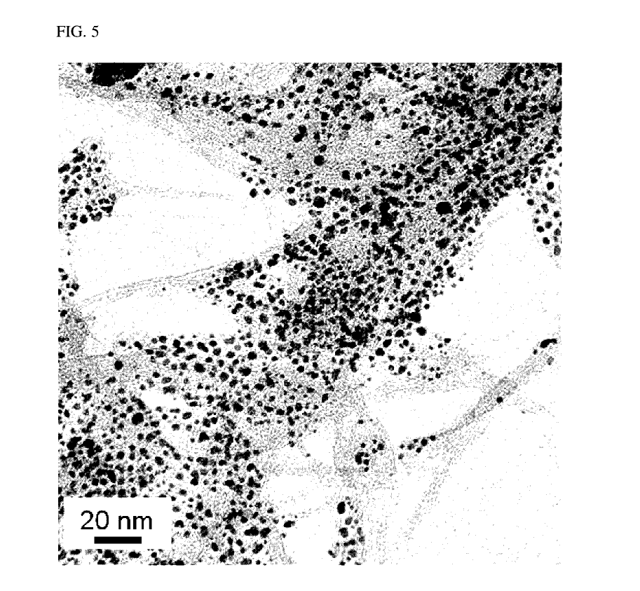

The platinum NPs may have an average diameter ranging from several to several tens of nanometers (nm), preferably from 2 to 10 nm When the average diameter of the platinum NPs falls within this range, it is preferable because a change in electric resistance due to gases in contact with the CNTs may be more sensitively measured. FIG. 3 shows platinum NPs decorated to surfaces of CNTs according to one exemplary embodiment of the present invention, FIGS. 4 to 6 show transmission electron microscope images of the substrate on which the CNTs and the platinum NPs are formed according to one exemplary embodiment of the present invention.

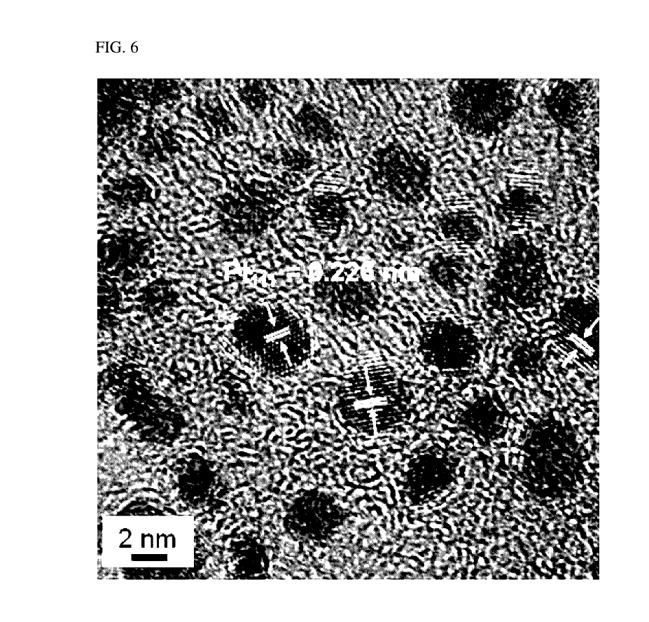

Referring to FIG. 6, the expression “Pt_{1 1 1}=0.226 nm” is indicated. Here, the term “Pt_{1 1 1}” represents an interplanar spacing of a (1 1 1) plane of platinum (Pt). Since this value represents platinum's inherent nature, the interplanar spacing shows that a material decorated to surfaces of CNTs is platinum. In this case, the Pt_{1 1 1} value is measured using high-resolution transmission electron microscopy.

An electrode is formed on the substrate on which the CNTs and the platinum NPs are formed as shown in FIGS. 4 to 6. The electrode may be a source electrode and a drain electrode. At least one metal selected from the group consisting of gold (Au), silver (Ag), chromium (Cr), tantalum (Ta), titanium (Ti), copper (Cu), aluminum (Al), molybdenum (Mo), tungsten (W), nickel (Ni), palladium (Pd), and platinum (Pt) may be used as a material of the electrode. A case in which platinum (Pt) and titanium (Ti) among these are used as the electrode is shown in FIG. 3.

A method of fabricating such a gas sensor includes (a) adsorbing CNTs onto a substrate, (b) depositing platinum (Pt) on the substrate onto which the CNTs are adsorbed, and (c) heat-treating the substrate onto which the platinum (Pt) is deposited to form platinum (Pt) NPs on surfaces of the CNTs.

Hereinafter, one exemplary embodiment of the method of fabricating a gas sensor will be described in detail with reference to FIGS. 1 to 3.

(a) Adsorption of CNTs on Substrate

First of all, a substrate is prepared. As described above, the substrate may include a silicon substrate or may include a silicon substrate having an insulator film formed on a surface thereof, for example, a silicon substrate (SiO₂/Si substrate) having a silicon oxide (SiO₂) film formed on a surface thereof. The insulator film may be formed on the substrate using a method such as a thermal oxidation method, a deposition method, a spin coating method, etc., but the present invention is not limited thereto. In the case of the thermal oxidation method, a thermal insulator film may be formed by heating the silicon substrate at temperature of 1,000° C. or more using a thermal diffusion furnace. In the case of the deposition method, a SiO₂ thin film may be formed on the silicon substrate using plasma-enhanced chemical vapor deposition (PECVD) or low-pressure CVD (LPCVD). In the case of the spin coating method, a SiO₂ thin film may be formed on the silicon substrate using spin-on-glass (SOG). A thickness of the insulator film may be in a range of 120 to 300 nm.

Next, CNTs are adsorbed onto the substrate. As described above, the CNTs preferably include SWCNTs. In the adsorption of the CNTs, the adsorption may be performed using a dipping method of dipping a substrate in a solution in which CNTs are dispersed and removing the substrate from the solution or a spraying method of spraying a solution in which CNTs are dispersed. To uniformly disperse the CNTs, the spraying method may be preferred. Such a spraying method may be carried out using an argon (Ar) gas in order to prevent an oxidation reaction of CNTs with oxygen. The use of the spraying method is shown in FIG. 1.

The solution may include at least one solvent selected from the group consisting of dichlorobenzene (DCB), ortho-dichlorobenzene (o-DCB), N-methyl-2-pyrrolidinone (NMP), hexamethylphosphoramide (HMPA), monochlorobenzene (MCB), N,N-dimethylformamide (DMF), dichloroethane (DCE), isopropyl alcohol (IPA), ethanol, chloroform, and toluene. Also, CNTs may be uniformly dispersed in the solution by applying ultrasonic waves to the solution.

In the solution in which the CNTs are dispersed, a concentration of the CNTs may be in a range of 0.01 to 0.50 mg/ml. When the concentration is less than 0.01 mg/ml, a function as a sensor may not be normally exerted due to a very small amount of adsorbed CNTs. On the other hand, when the concentration is greater than 0.50 mg/ml, a large amount of time is required to disperse the CNTs, sensitivity of the sensor may be degraded, and an excessive amount of the CNTs is consumed, resulting in increased manufacturing costs.

(b) Deposition of Platinum (Pt)

This operation includes depositing platinum (Pt) on the substrate onto which the CNTs are adsorbed. As a method of depositing the platinum (Pt), a conventional vacuum deposition may be used without limitation. For example, a method such as thermal evaporation, electron beam evaporation, sputtering, etc. may be used. Preferably, a sputtering method may be used.

For example, when the sputtering method is used, sputtering may be performed in an argon atmosphere in order to prevent an oxidation reaction of the CNTs with oxygen. Specifically, one exemplary embodiment of sputtering process conditions according to the present invention is described as follows:

Distance from target: 2 to 10 cm

Vacuum level of vacuum chamber: 5 to 20 mTorr

Vacuum level during vacuum deposition: 30 to 100 mTorr

(Provided that plasma is generated after the target is maintained in an argon atmosphere for at least 30 minutes)

Deposition time: 1 to 5 seconds

In the deposition of the platinum (Pt) on the substrate onto which the CNTs are adsorbed, surfaces of the CNTs may be coated with platinum to form a core-shell structure. Referring to FIG. 2, the core-shell structure is schematically shown. That is, in the deposition of the platinum (Pt), the CNTs are used as a core, and platinum is deposited to surround the surfaces of the CNTs, thereby forming a shell layer.

In the core-shell structure, a platinum (Pt) layer formed as the shell layer preferably has a thickness of 10 nm or less. More preferably, the thickness of the shell layer may be in a range of 5 nm to 10 nm When the thickness of the shell layer falls within this range, the shell layer of platinum (Pt) deposited on the substrate is preferably converted into NPs by a subsequent heat treatment.

(c) Heat Treatment Operation

This operation includes heat-treating the substrate on which the platinum (Pt) is deposited to form platinum (Pt) NPs on the surfaces of the CNTs. FIG. 2 is a diagram schematically showing platinum (Pt) NPs decorated to the surfaces of the CNTs, and FIGS. 4 to 6 show transmission electron microscope images of the substrate that underwent the heat treatment operation.

The heat treatment is performed to convert the shell layer of platinum (Pt) deposited on the substrate into NPs. In this case, energy used to cause the platinum (Pt) particles to self-agglomerate is provided. The heat treatment is preferably performed at a temperature of 500 to 600° C. When a heat treatment temperature is less than 500° C., it is difficult to form platinum (Pt) NPs that play a role as a catalyst. On the other hand, when the heat treatment temperature is greater than 600° C., Pt may be oxidized into PtO. Since PtO is a p-type semiconductor material, it is impossible to expect a Pt catalytic effect.

Such a heat treatment operation may be performed in an argon atmosphere to prevent oxidation of the CNTs and is preferably performed using a rapid thermal annealing furnace. The heat treatment operation is specifically described as follows. For example, a specimen is first mounted in a chamber and then maintained in a low vacuum state for 30 minutes or more. Then, argon gas is added to the chamber to minimize contact with oxygen. Then, the specimen is heated to 500 to 600° C. at a high speed for 1 to 5 minutes, maintained at that temperature for 30 minutes to 2 hours, and then quenched to RT. Accordingly, the heat treatment operation may be completed.

The average diameter of the platinum (Pt) NPs formed on the substrate onto which the CNTs are adsorbed by the heat treatment may be in a range of several nanometers to several tens of nanometers, preferably in a range of 2 to 10 nm

As shown in FIG. 3, a method of the present invention may further include forming an electrode on the substrate that underwent the heat treatment operation. Here, the electrode may be a source electrode and a drain electrode. A method of forming an electrode may be performed according to conventional photolithography process. For example, a metal or metal oxide thin film is formed on the substrate that underwent the above-described processes. The metal or metal oxide thin film may be formed in the form of a thin film using a method such as a vacuum deposition method including a thermal evaporation method, spin coating, roll coating, spray coating, or printing. An exposure process is performed on a top surface of the metal or metal oxide thin film to expose a region other than a source electrode and a drain electrode. Then, the metal or metal oxide thin film is etched using a conventional etching method, and a photoresist is finally removed with a photoresist stripper to form the source and drain electrodes made of the metal and metal oxide.

Hereinafter, the present invention will be described in further detail with reference to Examples thereof, but the present invention is not limited thereto.

### EXAMPLE 1

A SiO₂/Si substrate in which a silicon dioxide (SiO₂) insulator film was formed on the silicon substrate was prepared. In this case, a thickness of the insulator film was 300 nm.

SWCNTs were added to dichlorobenzene, and ultrasonic waves were applied to prepare a solution in which the SWCNTs were uniformly dispersed (see FIG. 1).

The concentration of the SWCNTs in the dispersion solution was 0.04 mg/ml.

The solution in which the SWCNTs were dispersed was sprayed onto the substrate using an air-brush spray gun (commercially available from Mr. Hobby; Model name: PS-770) so that the CNTs were adsorbed onto the substrate (see FIG. 1). In this case, the CNTs solution was sprayed using an argon (Ar) gas.

Platinum (Pt) was vacuum-deposited onto the substrate onto which the CNTs were adsorbed using a sputtering system (commercially available from SANYU ELECTRON COATER, Model name: SC-701MKII ADVANCE) (see FIG. 2). During the sputtering, a distance from a target was 3.5 cm, and a vacuum level of a vacuum chamber was adjusted to be 20 mTorr. After the vacuum level in the chamber was adjusted, argon (Ar) gas was injected from a gas tank, and maintained for 30 minutes. Then, plasma was generated while maintaining the vacuum level of the vacuum chamber at 50 mTorr. In this case, sputtering deposition was performed for 5 seconds. A platinum shell layer was deposited on surfaces of the CNTs by the vacuum deposition, and a thickness of the platinum shell layer was 5 nm

The substrate on which a platinum (Pt) thin film was vacuum-deposited was heat-treated using a rapid thermal annealing furnace (commercially available from ULVAC; Model name: MILA-3000). Specifically, the substrate was mounted in a chamber in the rapid thermal annealing furnace, and maintained in a low vacuum state for 30 minutes, and argon (Ar) gas was added to the chamber. Thereafter, the substrate was heated to 500° C. at a high speed for 1 minute, maintained for an hour, and then quenched to RT. The transmission electron microscope images of the substrate on which the heat treatment was completed are shown in FIGS. 4 to 6.

Next, a source electrode and a drain electrode were formed on the substrate on which platinum NPs were decorated according to a conventional photolithography process, thereby fabricating a gas sensor. In this case, Ti (50 nm)/Pt (200 nm) electrodes were used as the source electrode and the drain electrode (see FIG. 3)

### COMPARATIVE EXAMPLE 1

A SiO₂/Si substrate in which a silicon dioxide (SiO₂) insulator film was formed on the silicon substrate was prepared, and electrodes (Ni (20 nm)/Au (60 nm)) were then formed on the SiO₂/Si substrate according to a conventional photolithography process.

Next, SWCNTs were deposited on the substrate on which the electrodes were formed using CVD, thereby fabricating a gas sensor.

### COMPARATIVE EXAMPLE 2

An alumina (Al₂O₃) substrate was prepared, and electrodes (Cr (20 nm)/Au (350 nm)) were then formed on the alumina (Al₂O₃) substrate according to a conventional photolithography process.

Next, a MWCNT film was deposited on the substrate on which the electrodes were formed using radio-frequency PECVD (rf-PECVD), thereby fabricating a gas sensor.

### COMPARATIVE EXAMPLE 3

A Si₃N₄/Si substrate was prepared, and an electrode (Pt) was then formed on the Si₃N₄/Si substrate according to a conventional photolithography process.

Next, a CNT film was deposited on the substrate on which the electrode was formed using rf-PECVD, thereby fabricating a gas sensor.

### COMPARATIVE EXAMPLE 4

A polyimide substrate was prepared, and an electrode (Au) was then formed on the polyimide substrate according to a conventional photolithography process.

Next, the substrate on which the electrode was formed was spin-coated with an aqueous suspension of graphene oxide to form a graphene oxide film, and a CNT film was deposited on the graphene oxide film using PECVD, thereby fabricating a gas sensor. In this case, a thickness of the graphene oxide film was 7 nm, and a thickness of the CNT film was 20 μm. Here, the graphene oxide film was a reduced graphene oxide (RGO) film which was heat-treated at 600° C. in a mixture of hydrogen and ammonia gas.

Characterization of Gas Sensors

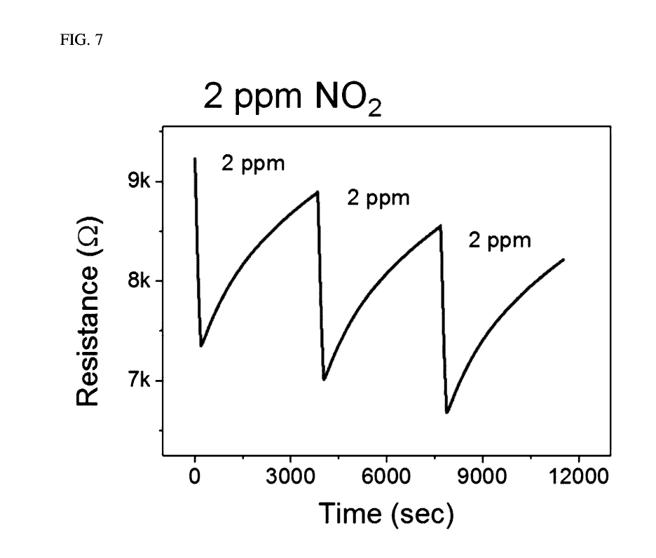

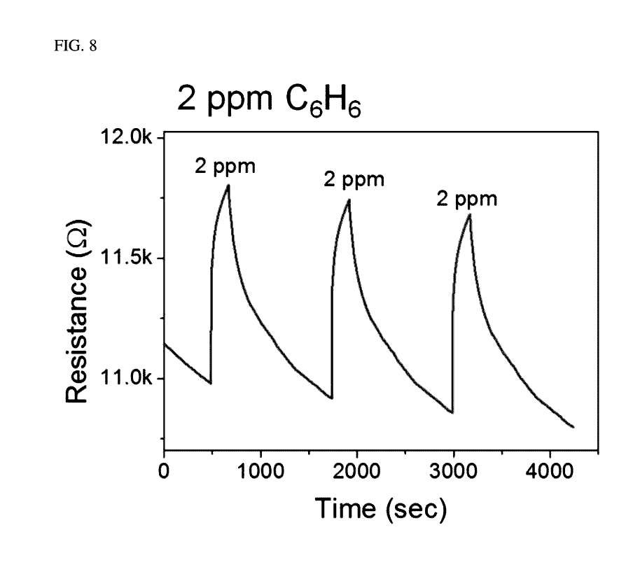

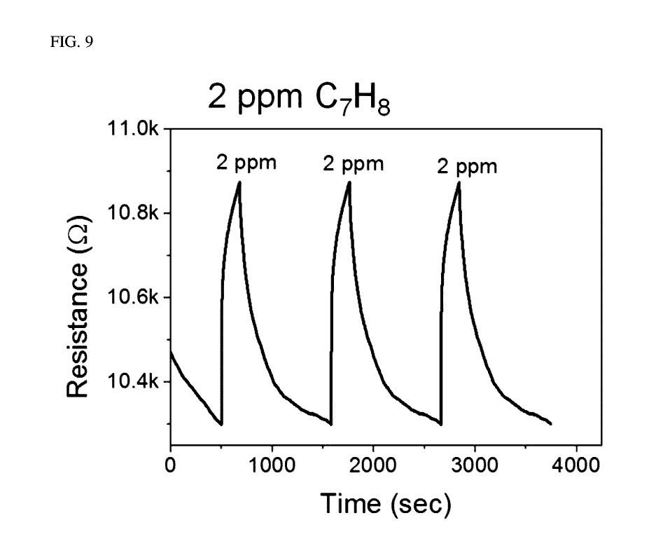

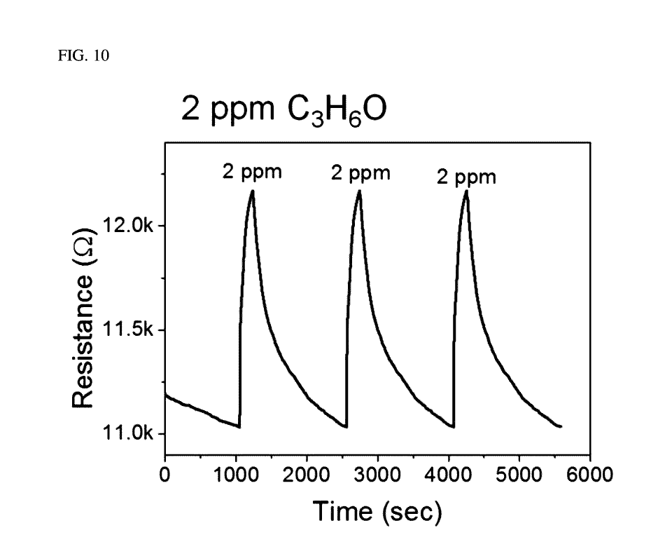

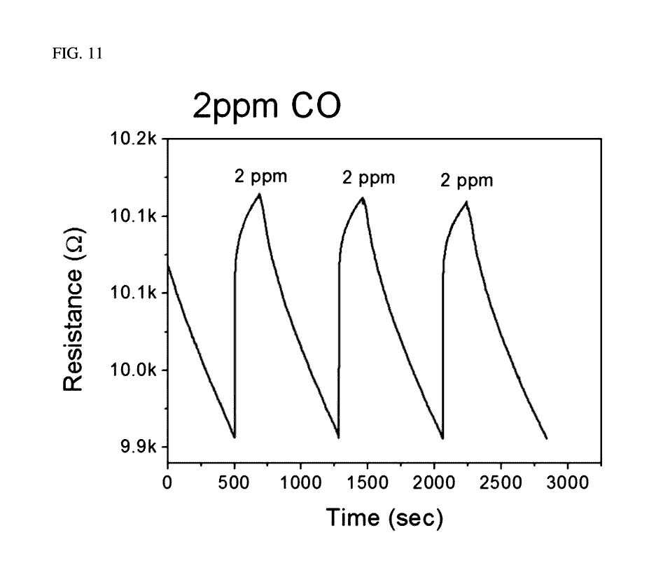

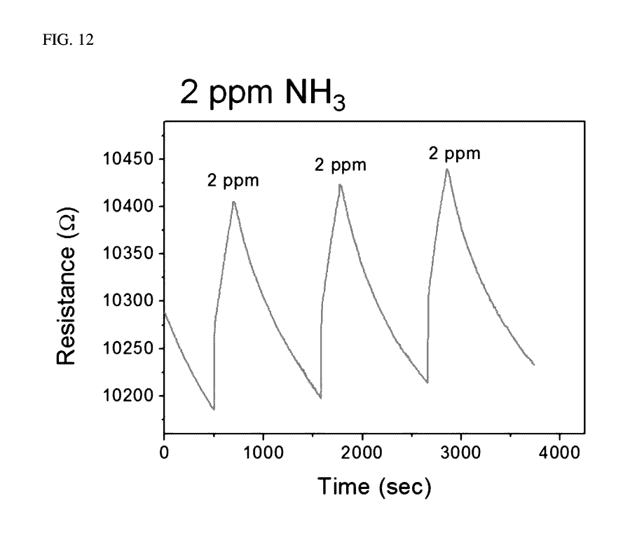

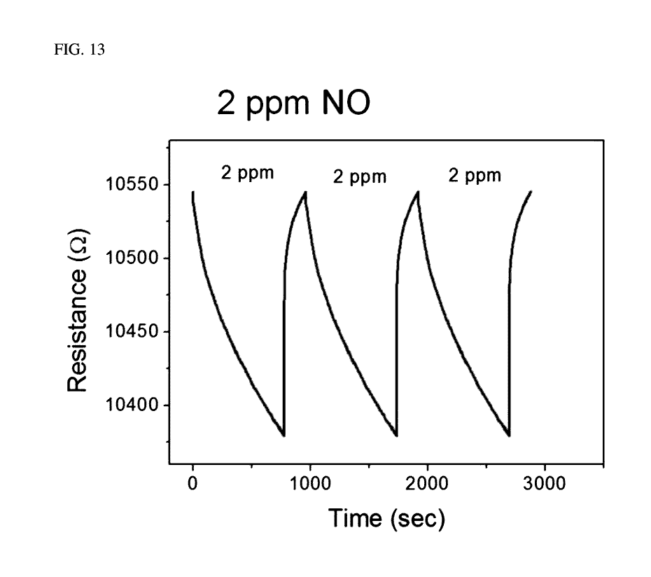

The gas sensor fabricated in Example 1 was connected to a direct current (DC) power supply (KEITHLEY 2400), and nitrogen dioxide (NO₂), benzene (C₆H₆), toluene (C₇H₈), acetone (C₃H₆O), carbon monoxide (CO), ammonia (NH₃) and nitrogen monoxide (NO) gases were allowed to flow thereto using a mass flow controller, and changes in resistance due to the adsorption of target gases-flowing around a sensing material were measured while applying a constant DC power source. The measurement results are shown in FIGS. 7 to 13. Types and concentrations of test gases are shown in each of drawings. All measurements were performed at RT.

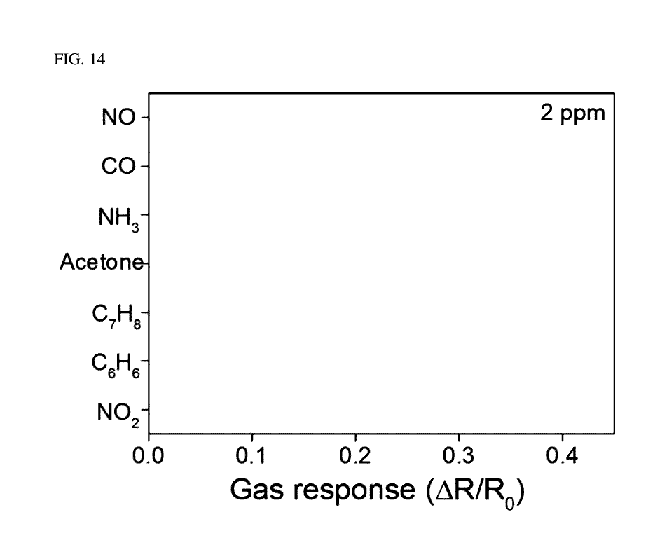

Sensitivities of the gas sensor to the test gases were calculated using the following Equation 1. A comparison of the sensitivities to the test gases calculated by the following equation is shown in FIG. 14. In this case, sensitivity measurement was performed at a gas concentration of 2 ppm.

Sensitivity=(ΔR/R₀) Equation 1

In Equation 1, R₀ represents an initial resistance value when there is no reactive gas, and AR represents a value obtained by subtracting the R₀ value from a resistance value when there is a reactive gas.

In the case of the gas sensors fabricated in Comparative Examples 1 to 4, NO₂ gas was allowed to flow thereto in the same manner as described above, and changes in resistance due to the adsorption of the NO₂ gas flowing around a sensing material were measured while applying a constant DC power source. As can be seen from the measurement results, response characteristics of the gas sensors with respect to the NO₂ gas are compared to those of the gas sensor of Example 1 and listed in the following Table 1. Here, the sensitivity (%) in the following Table 1 represents a value (%) obtained by multiplying the value calculated by Equation 1 by 100.

TABLE 1

| | Sensing | Detection | | Sensitivity | Response | | Operating | |
|---|---|---|---|---|---|---|---|---|
| | material | limit | | (%) | time | | temperature | Reversibility |
| Example 1 | Pt- | 2 | ppm | 37.5% | <180 | sec | RT | Reversible |
| | SWCNTs | | | | | | | |
| Comparative | SWCNTs | 2 | ppm | 6.5% | <600 | sec | RT | Irreversible |
| Example 1 | | | | | | | | |
| Comparative | MWCNTs | 1 | ppm | <3% | <90 | sec | 200° C. | Reversible |
| Example 2 | | | | | | | | (at 200° C.) |
| Comparative | CNT film | 10 | ppb | <2% | 120 | min | 165° C. | Reversible |
| Example 3 | | | | | | | | (at 165° C.) |
| Comparative | CNT/RGO | 2 | ppm | <8% | <60 | min | RT | Irreversible |
| Example 4 | fiml | | | | | | | |

Referring to Table 1, it was confirmed that the gas sensor of Example 1 in which the platinum NPs and CNTs were used as the sensing material according to the present invention had a somewhat low or similar detection limit as compared to those of the gas sensors of Comparative Examples 1 to 4, but that the gas sensor of Example 1 was able to detect a gas present at a low concentration of 2 ppm and exhibited high sensitivity. Also, it could be seen that the gas sensors of Comparative Examples 1 and 4 were operable at RT like the gas sensor of Example 1, but had a slow response time and non-reversible characteristics. Further, it could be seen that the gas sensors of Comparative Examples 2 and 3 were not operable at RT.

Also, referring to FIGS. 7 to 13, it could be seen that the gas sensor fabricated in Example 1 was able to sense benzene (C₆H₆), toluene (C₇H₈), acetone (C₃H₆O), carbon monoxide (CO), ammonia (NH₃) and nitrogen monoxide (NO) gases in addition to nitrogen dioxide (NO₂) gas even when the gases were present at a very low concentration of 2 ppm, and exhibited stable and repetitive resistance characteristics over time. In particular, referring to FIG. 14, it could be seen that the Pt-SWCNT sensor fabricated in Example 1 of the present invention had very excellent selectivity with respect to NO₂ gas.

According to the present invention, a gas sensor and a method of fabricating the same can be provided. Here, when the platinum NPs and CNTs are used as the sensing material, the gas sensor can be useful in sensing gases with high sensitivity even when the gases are present at a low concentration of at least 2 ppm, stably sensing noxious gases such as C₆H₆, C₇H₈, C₃H₆O, CO, NO, and NH₃ as well as NO₂, and can have particularly excellent selectivity and response characteristics with respect to NO₂ gas.

Further, the gas sensor according to one exemplary embodiment of the present invention can have an effect of minimizing power consumption since the gas sensor is operable at RT without using a heater.

It should be apparent to those skilled in the art that various modifications can be made to the above-described exemplary embodiments of the present invention without departing from the scope of the invention. Thus, it is intended that the present invention covers all such modifications provided they come within the scope of the appended claims and their equivalents.

What is claimed is:

1. A gas sensor comprising:
a substrate;
carbon nanotubes (CNTs) adsorbed onto the substrate;
platinum nanoparticles (NPs) decorated to surfaces of the CNTs; and
an electrode formed on the substrate onto which the CNTs with the platinum NPs decorated thereto are adsorbed.

2. The gas sensor of claim 1, wherein the substrate comprises a silicon substrate.

3. The gas sensor of claim 1, wherein the substrate comprises a silicon substrate having a silicon dioxide film formed on a surface thereof.

4. The gas sensor of claim 1, wherein the CNTs comprise single-walled CNTs (SWCNTs).

5. The gas sensor of claim 1, wherein the platinum NPs have an average diameter of 2 nm to 10 nm.

6. A method of fabricating a gas sensor, comprising:
(a) adsorbing carbon nanotubes (CNTs) onto a substrate;
(b) depositing platinum (Pt) onto the substrate onto which the CNTs are adsorbed; and
(c) heat-treating the substrate onto which the platinum (Pt) is deposited to form platinum (Pt) nanoparticles (NPs) on surfaces of the CNTs.

7. The method of claim 6, wherein the substrate comprises a silicon substrate.

8. The method of claim 6, wherein the substrate comprises a silicon substrate having a silicon dioxide film formed on a surface thereof.

9. The method of claim 6, wherein the CNTs comprises single-walled CNTs (SWCNTs).

10. The method of claim 6, wherein, in the absorbing of the CNTs onto the substrate, the absorption is performed in an argon atmosphere using a spraying method.

11. The method of claim 6, wherein, in the depositing of the platinum (Pt) on the substrate onto which the CNTs are adsorbed, the platinum (Pt) is coated onto the surfaces of the CNTs to form a core-shell structure.

12. The method of claim 11, wherein a platinum (Pt) layer formed as a shell layer in the core-shell structure has a thickness of 5 nm to 10 nm.

13. The method of claim 6, wherein the heat treatment is performed at 500 to 600° C.

14. The method of claim 6, wherein the platinum NPs have an average diameter of 2 nm to 10 nm.

15. The method of claim 6, wherein the heat treatment is performed in argon atmosphere.

16. The method of claim 6, wherein the heat treatment is performed using a rapid thermal annealing furnace.

17. The method of claim 6, further comprising:
forming an electrode on the substrate that underwent heat treatment operation.
